(19) United States
(12) Patent Application Publication
(10) Pub. No.: US 2026/0190427 A1
(43) Pub. Date: Jul. 2, 2026

(54) SEMICONDUCTOR DEVICE AND METHOD FOR FABRICATING THE SAME

(71) Applicant: United Microelectronics Corp., Hsinchu (TW)

(72) Inventors: Shin-Hung LI, Nantou County (TW); Ming-Hua TSAI, Tainan City (TW); Yueh-Chang LIN, Tainan City (TW); Shan-Shi HUANG, Hsinchu City (TW)

(21) Appl. No.: 19/050,150

(22) Filed: Feb. 11, 2025

(30) Foreign Application Priority Data
Dec. 31, 2024 (TW) 113151654

(51) Int. Cl. H10D 64/27; H10D 30/01; H10D 30/60; H10D 64/01

(52) U.S. Cl. CPC H10D 64/516; H10D 30/0212; H10D 30/022; H10D 30/601; H10D 64/017; H10D 64/021

(57) ABSTRACT

A semiconductor device includes a substrate, a dielectric layer, a gate structure, a lightly doped region, a first spacer and a heavily doped region. The dielectric layer is disposed on the substrate and includes a first section with a first thickness and a second section with a second thickness, the first thickness is greater than the second thickness, and the second section surrounds the first section. The gate structure covers a portion of the first section. The lightly doped region is formed in the substrate and adjacent to the gate structure. The first spacer is disposed on sidewalls of the gate structure and covers another portion of the first section. The heavily doped region is disposed in the lightly doped region and adjacent to the second section.

This application claims the benefit of Taiwan Application Serial No. 113151654 filed at Dec. 31, 2024 the subject matter of which is incorporated herein by reference.

### BACKGROUND

### Technical Field

The disclosure relates to a semiconductor device and the method for fabricating the same, and more particularly to a semiconductor device with an offset gate structure and the method for fabricating the same.

### Description of Background

Generally, gate offset technology is applied to a field effect transistor structures to form a non-overlapping area (offset distance) between the source and the gate and/or between the drain and the gate to prevent the gate from being affected by the high electric field occurred near the drain, so as to achieve the purposes of high voltage resistance, reducing source resistance and improving device characteristics. It is commonly combined with a self-aligned silicide process, in which a self-aligned silicide block (SAB) is firstly formed around the gate, and the source/drain is then formed in the semiconductor substrate. Subsequently, a metal silicide layer is formed on the gate and the drain/source. Since the gate is separated from the drain/source by the SAB, thus the gate deviates from the source/drain for an additional (offset) distance, thereby achieving the purpose of high voltage resistance of the device.

However, the silicide process requires a larger process margin, as the critical dimensions of semiconductor devices continue to shrink, the process margin that can be provided will be compressed, which may affect the process yield of the semiconductor devices.

Therefore, there is a need of providing an advanced semiconductor device and the method for fabricating the same to obviate the drawbacks encountered from the prior art.

### SUMMARY

One aspect of the present disclosure is to provide a semiconductor device, wherein the semiconductor device includes a substrate, a dielectric layer, a gate structure, a lightly doped region, a first spacer and a heavily doped region. The dielectric layer is disposed on the substrate and includes a first section with a first thickness and a second section with a second thickness, the first thickness is greater than the second thickness, and the second section surrounds the first section. The gate structure covers a portion of the first section. The lightly doped region is formed in the substrate and adjacent to the gate structure. The first spacer is disposed on sidewalls of the gate structure and covers another portion of the first section. The heavily doped region is disposed in the lightly doped region and adjacent to the second section.

Another aspect of the present disclosure is to provide a method for fabricating a semiconductor device, wherein the method includes steps as follows: A substrate is firstly provided and a dielectric layer is then formed on the substrate. Next, a gate structure is formed on the dielectric layer. A lightly doped region is formed in the substrate and adjacent to the gate structure. The dielectric layer is then thinned to make the dielectric layer including a first section with a first thickness and a second section with a second thickness, wherein the first thickness is greater than the second thickness, and the second section surrounds the first section. Subsequently, a first spacer is formed on sidewalls of the gate structure and covers a portion of the first section; and a heavily doped region is formed in the lightly doped region and adjacent to the second section.

According to the aforementioned embodiments, the present disclosure provides a semiconductor device and a method for fabricating the same, which includes following steps: A dielectric layer is firstly formed on a semiconductor substrate and then a gate structure is formed on the dielectric layer. An ion implantation is performed using the gate structure as a mask to form a lightly doped drain region in the semiconductor substrate. A portion of the dielectric layer is then thinned by a dry etching process to leave a portion of the dielectric layer not being thinned protrudes and surrounds the peripheral area of the gate structure. Then, a spacer is formed on the sidewalls of the gate structure to partially cover the portion of the dielectric layer not being thinned. Next, the thinned portion of the dielectric layer is removed by a cleaning or an etching process. At the same time, another thinning process is performed on the portion of the dielectric layer that has not been thinned and is not covered by the gate structure, so as to make the remaining portion of the dielectric layer have a two-layers stepped structure. Afterwards, another ion implantation process is performed using the gate structure, the spacer and the two-layers stepped structure as a mask to form a source/drain in the semiconductor substrate.

Since the gate structure is disposed on a first section with a larger thickness in the two-layers stepped structure of the dielectric layer, and a second section with a thinner thickness in the two-layers stepped structure of the dielectric layer surrounds the first section, thus it can make the gate structure deviate from the source/drain for a certain distance, such that the invention purpose of making the device withstand high pressure is thereby achieved. In addition, since the two-layers stepped structure of the dielectric layer is prepared by a photolithography and etching process which provide higher process precision, thus it can better cope with the miniaturization of critical dimensions and improve the process yield of semiconductor components.

### BRIEF DESCRIPTION OF THE DRAWINGS

The above objects and advantages of the present disclosure will become more readily apparent to those ordinarily skilled in the art after reviewing the following detailed description and accompanying drawings, in which:

FIGS. 1A to 1H are cross-sectional views illustrating a series of processing structures for fabricating a semiconductor device, according to one embodiment of the present disclosure.

### DETAILED DESCRIPTION

The embodiments as disclosed below provide a semiconductor device and the method for fabricating the same, which can make the semiconductor device resistant to high voltage and providing well yield while the critical dimension thereof shrinks. The present disclosure will now be described more specifically with reference to the following embodiments illustrating the structure, method and arrangements thereof.

It is to be noted that the following descriptions of preferred embodiments of this disclosure are presented herein for purpose of illustration and description only. It is not intended to be exhaustive or to be limited to the precise form disclosed. In addition, it is important to point out that there may be other features, elements, steps, and parameters for implementing the embodiments of the present disclosure, which are not specifically illustrated. Thus, the descriptions and the drawings are to be regard as an illustrative sense rather than a restrictive sense. Various modifications and similar arrangements may be provided by the persons skilled in the art within the spirit and scope of the present disclosure. In addition, the illustrations may be not drawn to scale, and the identical elements of the embodiments are designated with the same reference numerals.

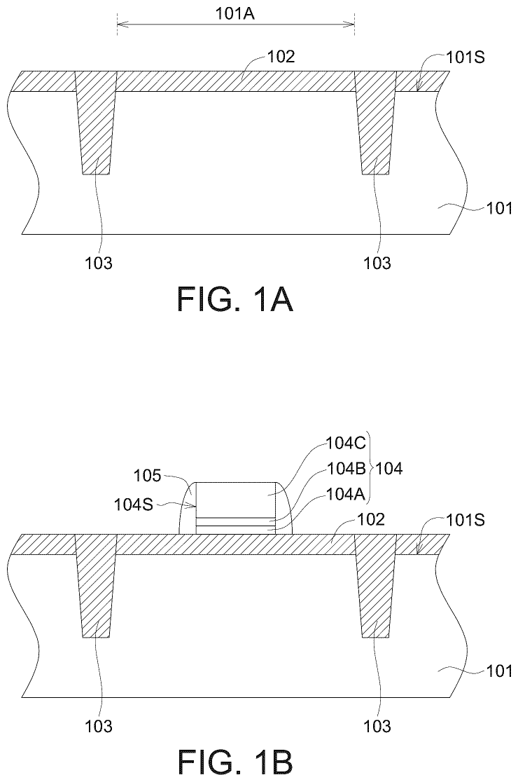

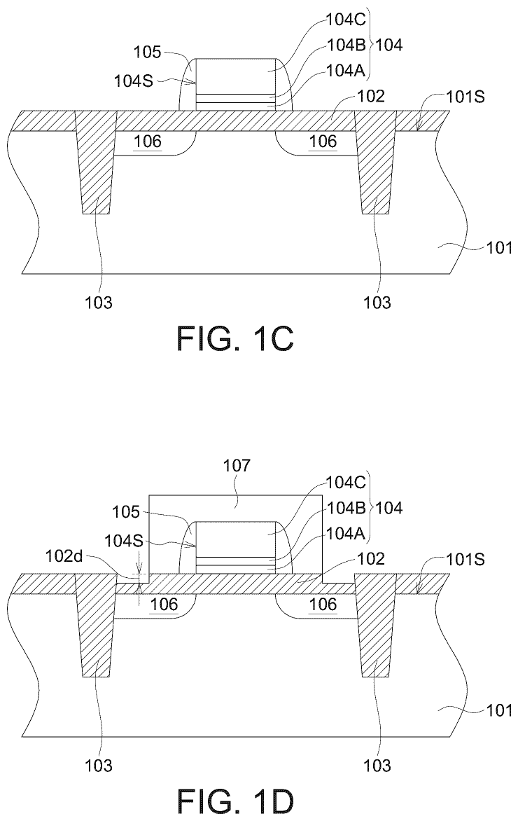

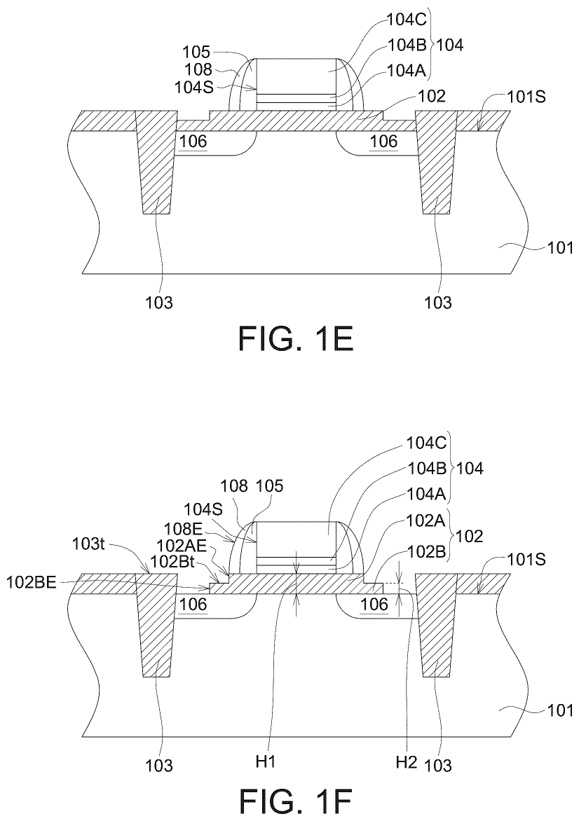

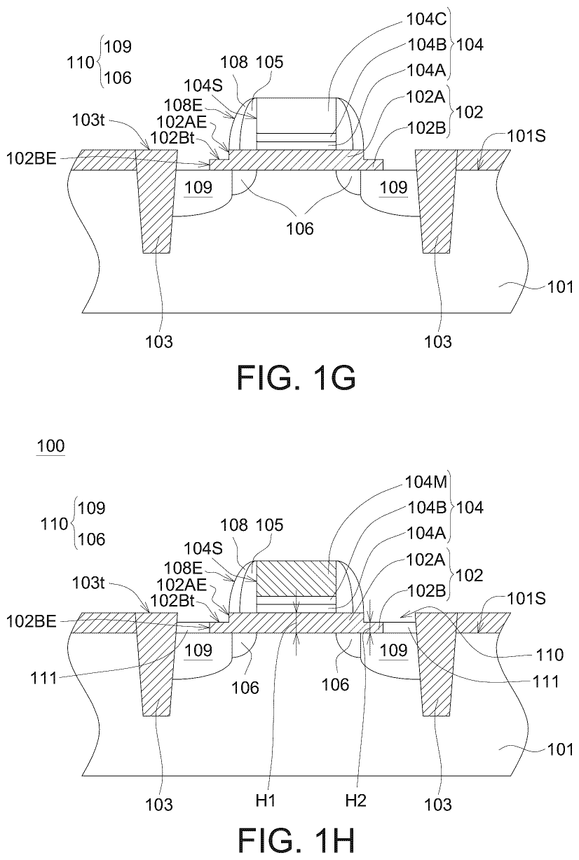

FIGS. 1A to 1H are cross-sectional views illustrating a series of processing structures for fabricating a semiconductor device 100, according to one embodiment of the present disclosure. The method for fabricating the semiconductor device 100 includes steps as follows: Firstly, a substrate 101 is provided; and then a dielectric layer 102 is formed on the substrate 101 (as shown in FIG. 1A). In some embodiments of the present disclosure, the substrate 101 may be made of a semiconductor material, for example, silicon (Si), germanium (Ge), or a compound semiconductor material, such as gallium arsenide (GaAs). The dielectric layer 102 may include silicon oxide, silicon oxynitride, silicon carbide, silicon nitride, or any combination thereof.

In the present embodiment, the substrate 101 may preferably be a silicon wafer. After the dielectric layer 102 is formed, an insulating structure (e.g., a shallow trench isolation structure (STI)) 103 may be formed in the substrate 101 by a lithography and etching process and a dielectric material deposition process, wherein the insulating structure 103 extends passing through the electrical layer 102 and the substrate surface 101S of the substrate 101 and downward into the substrate 101, thereby an active region 101A is defined in the substrate 101.

Next, a gate structure 104 is formed on the dielectric layer 102 (as shown in FIG. 1B). In some embodiments of the present disclosure, the gate structure 104 includes: a high-k dielectric layer 104A, a work function barrier layer 104B, and a gate electrode 104C. The high-k dielectric layer 104A is disposed above a first section 102A of the dielectric layer 102 and covers a portion of the first section 102A. The work function barrier layer 104B is disposed above the high-k dielectric layer 104A. The gate electrode 104C is disposed above the work function barrier layer 104B.

The formation of the gate structure 104 includes steps as follows: Firstly, a dielectric material layer, a work function barrier layer, and a metal layer are sequentially formed on the dielectric layer 102 by using multiple deposition processes (e.g., a plurality of chemical vapor deposition (CVD) processes). Next, an etching process (e.g., reactive ion etching (RIE) or other dry etching processes) is performed to remove portions of the metal layer, the work function barrier layer and the dielectric layer, so as to form the gate structure 104. Afterwards, a spacer 105 is formed on the sidewalls 104S of the gate structure 104.

In the present embodiment, the high-k dielectric layer 104A includes hafnium dioxide (HfO₂), zirconium dioxide (ZrO₂), titanium dioxide (TiO₂), aluminum oxide (Al₂O₃), yttrium oxide (Y₂O₃), tantalum pentoxide (Ta₂O₅) . . . etc. The work function barrier layer 104B includes titanium nitride. The gate electrode 104C includes polysilicon. The spacer 105 includes silicon oxide, and covers not only on the sidewalls 104S of the gate structure 104, but also on a portion of the dielectric layer 102.

Then, a lightly doped region 106 is formed in the substrate 101 and adjacent to the gate structure 104 (as shown in FIG. 1C). The formation of the lightly doped region 106 includes performing an ion implantation process on the substrate 101 using the gate structure 104 and the spacer 105 as a mask to implant p-type dopants (boron (B), aluminum (Al), gallium (Ga)) or n-type dopants (phosphorus (P), antimony (Sb), arsenic (As)) into the substrate 101 to form the lightly doped region 106.

Then, the dielectric layer 102 is thinned to make the dielectric layer 102 including a first section 102A with a first thickness H1 and a second section 102B with a second thickness H2, wherein the first thickness H1 is greater than the second thickness H2, and the second section 102B surrounds the first section 102A. The thinning of the dielectric layer 102 includes steps as follows: Firstly, a patterned photoresist layer 107 is a formed by using a reticle to cover the gate structure 104, the spacer 105 and a portion of the dielectric layer 102 surrounding the gate structure 104. A dry etching process is then performed to remove the portion of the dielectric layer 102 that is not covered by the patterned photoresist layer 107. The thickness 102d of the dielectric layer 102 not covered by the patterned photoresist layer 107 is smaller than the original thickness H1 of the dielectric layer 102 (as shown in FIG. 1D).

In some embodiments of the present disclosure, the etching process for thinning the dielectric layer 102 does not completely remove the portion of the dielectric layer 102 that is not covered by the patterned photoresist layer 107, so that the portion of the substrate 101 underneath the thinned portion of the dielectric layer 102 is still not exposed outside. On the contrary, there is still a thin film of the thinned portion of the dielectric layer 102 that is not covered by the patterned photoresist layer 107 remained on a portion of the substrate 101 used to protect the substrate 101. The remaining thin layer (part of the dielectric layer 102) will be then removed by a treatment agent (e.g., a wet cleaning solution or an etchant) in a pre-cleaning step of a subsequent process, thereby a portion of the lightly doped region 106 that is not covered by the patterned photoresist layer 107 is exposed to the outside (as described below).

After removing the patterned photoresist layer 107, a spacer 108 is formed on the sidewalls 104S of the gate structure 104, covering on the spacer 105 and covering on the portion of the dielectric layer 102 that has not been thinned, so as make the spacer 105 disposed between the sidewall 104S of the gate structure 104 and the spacer 108. In the present embodiment, the spacer 108 includes silicon nitride (as shown in FIG. 1E).

A cleaning/etching back process is then performed to remove the thinned portion of the dielectric layer 102 that is not covered by the patterned photoresist layer 107, thereby exposing a portion of the lightly doped region 106. At the same time, the portion of the dielectric layer 102 previously covered by the patterned photoresist layer 107 but not covered by the gate structure 104, the spacers 105 and 108, is thinned down. Such that, the remained dielectric layer 102 can be divided into a first section 102A with an original thickness H1 and a second section 102B with a thinned thickness H2, wherein the original thickness H1 is greater than the thinned thickness H2, and the remained dielectric layer 102 has a two-layers stepped structure. The outer edge 108E of the spacer 108 is aligned with the outer sidewall 102AE of the first section 102A; and the upper surface 102Bt of the second section 102B is lower than the upper surface 103t of the insulating structure (STI) 103. (As shown in FIG. 1F).

Next, another ion implantation process is performed to form a heavily doped region 109, having a doping concentration greater than that of the lightly doped region 106 in the lightly doped region 106, and adjacent to the second section 102B of the dielectric layer 102. Thereby a source/drain 110 is formed adjacent to the gate structure 104. In the present embodiment, the doped region 109 extends below the end of the second section 102B away from the sidewall 104S of the gate structure 104, so that the source/drain 110 deviates from the gate structure 104 by a distance.

Thereafter, the second section 102B of the dielectric layer 102 is used as a SAB to perform a silicide process to form a metal silicide layer 111 on the heavily doped region 109 (source/drain 110) (as shown in FIG. 1G).

Subsequently, the silicon gate electrode 104C of the gate structure 104 is removed and then replaced with a metal gate electrode 104M. Thereafter, a series of down-stream processes are performed to form an interconnection structure (not shown) electrically connected to the metal gate electrode 104M and the source/drain 110, and to complete the preparation of the semiconductor device 100 (as shown in FIG. 1H).

By forming the dielectric layer 102 that has the first section 101A and the second section 102B in combination to form a two-layers stepped structure, the gate structure 104 can be deviated from the source/drain 110 for a distance, thereby achieving the purpose of high voltage resistance of the semiconductor device 100. In addition, since the first section 101A and the second section 102B of the dielectric layer 102 are formed by photolithography and etching processes, by which higher process precision can be provided, thus it can better cope with the miniaturization of critical dimensions and improve the process yield. Moreover, since the second section 102B of the dielectric layer 102 can serve as a SAB to replace the prior art self-aligned metal, thus the steps and cost for forming the silicide layer 111 on the heavily doped region 109 (source/drain 110 can be beneficially reduced.

According to the aforementioned embodiments, the present disclosure provides a semiconductor device and a method for fabricating the same, which includes following steps: A dielectric layer is firstly formed on a semiconductor substrate and then a gate structure is formed on the dielectric layer. An ion implantation is performed using the gate structure as a mask to form a lightly doped drain region in the semiconductor substrate. A portion of the dielectric layer is then thinned by a dry etching process to leave a portion of the dielectric layer not being thinned protrudes and surrounds the peripheral area of the gate structure. Then, a spacer is formed on the sidewalls of the gate structure to partially cover the portion of the dielectric layer not being thinned. Next, the thinned portion of the dielectric layer is removed by a cleaning or an etching process. At the same time, another thinning process is performed on the portion of the dielectric layer that has not been thinned and is not covered by the gate structure, so as to make the remaining portion of the dielectric layer have a two-layers stepped structure. Afterwards, another ion implantation process is performed using the gate structure, the spacer and the two-layers stepped structure as a mask to form a source/drain in the semiconductor substrate.

Since the gate structure is disposed on a first section with a larger thickness in the two-layers stepped structure of the dielectric layer, and a second section with a thinner thickness in the two-layers stepped structure of the dielectric layer surrounds the first section, thus it can make the gate structure deviate from the source/drain for a certain distance, such that the invention purpose of making the device withstand high pressure is thereby achieved. In addition, since the two-layers stepped structure of the dielectric layer is prepared by a photolithography and etching process which provide higher process precision, thus it can better cope with the miniaturization of critical dimensions and improve the process yield of semiconductor components.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor device, comprising:
a substrate;
a dielectric layer, disposed on the substrate and comprising a first section with a first thickness and a second section with a second thickness, wherein the first thickness is greater than the second thickness, and the second section surrounds the first section;
a gate structure, covering a portion of the first section;
a lightly doped region, formed in the substrate and adjacent to the gate structure;
a first spacer, disposed on a sidewall of the gate structure and covering another portion of the first section; and
a heavily doped region, disposed in the lightly doped region and adjacent to the second section.

2. The semiconductor device according to claim 1, wherein the first section and the second section together form a stepped structure.

3. The semiconductor device according to claim 1, wherein the dielectric layer comprises silicon oxide; and the gate structure comprises:
a high-k dielectric layer, disposed on a portion of the first section;
a work function barrier layer, disposed on the high-k dielectric layer; and
a metal gate, disposed on the work function barrier layer.

4. The semiconductor device according to claim 1, wherein the heavily doped region extends below an end of the second section away from the sidewall.

5. The semiconductor device according to claim 1, further comprising a second spacer disposed between the sidewall and the first spacer and covering the another portion of the first section.

6. The semiconductor device according to claim 5, wherein the second spacer comprises silicon oxide; the first spacer comprises silicon nitride.

7. The semiconductor device according to claim 5, wherein an outer edge of the spacer is aligned with an outer sidewall of the first section.

8. The semiconductor device according to claim 1, further comprising an insulating structure disposed an outside of the heavily doped region.

9. The semiconductor device according to claim 8, wherein an upper surface of the second section is lower than an upper surface of the insulating structure.

10. A method for fabricating a semiconductor device, comprising:
providing a substrate;
forming a dielectric layer on the substrate;
forming a gate structure on the dielectric layer;
forming a lightly doped region in the substrate and adjacent to the gate structure;
thinning the dielectric layer, to make the dielectric layer including a first section with a first thickness and a second section with a second thickness, wherein the first thickness is greater than the second thickness, and the second section surrounds the first section;
forming a first spacer on sidewalls of the gate structure and covers a portion of the first section; and
forming a heavily doped region in the lightly doped region and adjacent to the second section.

11. The method according to claim 10, wherein the step of thinning the dielectric layer comprises:
forming a patterned photoresist layer to cover the gate structure a portion of the dielectric layer surrounding the gate structure;
performing a dry etching process to remove another portion of the dielectric layer that is not covered by the patterned photoresist layer;
removing the patterned photoresist layer and forming the first spacer; and
performing a cleaning/etching back process to remove the another portion of the dielectric layer that is not covered by the patterned photoresist layer; and thinning a portion of the dielectric layer that is not covered by the gate structure and the first spacer.

12. The method according to claim 10, wherein the step of forming the gate structure comprises:
forming a patterned high-k dielectric layer on the dielectric layer;
forming a work function barrier layer on the patterned high-k dielectric layer; and
forming a silicon gate electrode on the work function barrier layer.

13. The method according to claim 12, further comprising steps of replacing the silicon gate electrode with a metal gate electrode.
